(19) United States
(12) Patent Application Publication
(10) Pub. No.: US 2023/0238942 A1
(43) Pub. Date: Jul. 27, 2023

(54) RECEIVING APPARATUS

(71) Applicants: AutoNetworks Technologies, Ltd., Yokkaichi-shi, Mie (JP); Sumitomo Wiring Systems, Ltd, Yokkaichi-shi, Mie (JP); Sumitomo Electric Industries, Ltd., Osaka-shi, Osaka (JP)

(72) Inventors: Nobuyuki KOBAYASHI, Yokkaichi-shi, Mie (JP); Tadashi MATSUMOTO, Yokkaichi-shi, Mie (JP); Takeshi HAGIHARA, Yokkaichi-shi, Mie (JP); Yuanjun XIAN, Yokkaichi-shi, Mie (JP); Makoto MASHITA, Yokkaichi-shi, Mie (JP)

(21) Appl. No.: 18/002,363

(22) PCT Filed: Jun. 17, 2021
(86) PCT No.: PCT/JP2021/023003

§ 371 Date: Dec. 19, 2022

(30) Foreign Application Priority Data
Jun. 26, 2020 (JP) 2020-110788

(51) Int. Cl. H03H 11/04; H04B 3/50

(52) U.S. Cl. CPC H03H 11/04; H04B 3/50

(57) ABSTRACT

A differential signal represented by a voltage difference between two signals that propagate through two signal lines is input to a signal processing circuit from a connector. A first suppressing circuit and a second suppressing circuit suppress peak values of the two signals. A DC removing circuit removes DC components of the two signals. A common mode choke coil (noise removing circuit) removes common mode noise included in the two signals. The DC removing circuit and the noise removing circuit are disposed between the first suppressing circuit and the second suppressing circuits. If the voltage of the signal line is a first threshold voltage, a current flows through a first suppressing device (first connection device). If the voltage of the signal line is a second threshold voltage, a current flows through a second suppressing device (second connection device). The second threshold voltage is less than the first threshold voltage.

### CROSS-REFERENCE TO RELATED APPLICATIONS

This application is the U.S. national stage of PCT/JP2021/023003 filed on Jun. 17, 2021, which claims priority of Japanese Patent Application No. JP 2020-110788 filed on Jun. 26, 2020, the contents of which are incorporated herein.

### TECHNICAL FIELD

The present disclosure relates to a receiving apparatus.

### BACKGROUND

JP 2018-74432A discloses a vehicle communication system in which communication apparatuses communicate with one another. The communication apparatuses are electronic control units (ECUs), for example. In the communication system disclosed in JP 2018-74432A, the communication apparatuses are connected to each other by communication lines formed by two signal lines. Each communication apparatus transmits a differential signal represented by a voltage difference between two signals that propagate through the two signal lines, and receives a differential signal by detecting the voltage difference between the two signal lines.

Each communication apparatus includes a suppressing circuit for suppressing the peak values of the two signals that propagate through the two signal lines, a noise removing circuit for removing common mode noise from the two signals, a DC removing circuit for removing DC components from the two signals, and a conversion circuit for converting differential signals into digital signals. Common mode noise is noise that propagates in the same direction on the two signal lines. When a communication apparatus receives a differential signal, the communication apparatus first inputs the two signals that propagate through the two signal lines to the suppressing circuit where the peak values of the two signals are suppressed. The two signals whose peak values have been suppressed are input to the noise removing circuit where common mode noise is removed from the two signals. The two signals from which common mode noise has been removed are input to the DC removing circuit where DC components are removed from the two signals. The two signals whose DC components have been removed are input to the conversion circuit where the differential signal represented by the voltage difference between the two signals is converted into a digital signal.

The generation of static electricity may lead to a high voltage being input to the communication apparatuses. In the communication apparatuses disclosed in JP 2018-74432A, the peak values are suppressed, and thus the application of a high voltage to the noise removing circuit, the DC removing circuit, and the conversion circuit is prevented.

Normally, the voltage that is allowed to be applied to a conversion circuit is small. On the other hand, communication standards stipulate that suppressing a peak value of a signal input to a communication apparatus to a value smaller than a predetermined value is prohibited. In this case, in the configuration disclosed in JP 2018-74432A, there may be cases where peak values of the two signals whose DC components have been removed are not suppressed to a small value and a voltage greater than the allowable voltage is applied to the conversion circuit.

Thus, it is an object of the present invention to provide a receiving apparatus in which the peak values of two signals whose DC components have been removed are reliably suppressed to a small value.

### SUMMARY

A receiving apparatus according to one aspect of the present disclosure that receives a differential signal represented by a voltage difference between two signals that propagate through two signal lines, the receiving apparatus including: a first suppressing circuit and a second suppressing circuit configured to suppress peak values of the two signals; a DC removing circuit configured to remove DC components of the two signals; and a noise removing circuit configured to remove common mode noise included in the two signals, wherein, on a propagation path of the two signals, the DC removing circuit and the noise removing circuit are disposed between the first and second suppressing circuits, the differential signal propagates to the first suppressing circuit and the second suppressing circuit in this order, the first suppressing circuit includes two first connection devices respectively connected at one end to the two signal lines, if the voltage of the signal lines is a first threshold voltage, a current flows through the respective first connection devices, the second suppressing circuit includes two second connection devices respectively connected at one end to the two signal lines, if the voltage of the signal lines is a second threshold voltage, a current flows through the respective second connection devices, and the second threshold voltage is less than the first threshold voltage.

### Advantageous Effects of the Present Disclosure

With the present disclosure, peak values of two signals whose DC components have been removed are reliably suppressed to a small value.

### BRIEF DESCRIPTION OF DRAWINGS

FIG. 1 is a block diagram showing the main configuration of a communication system of the present embodiment.

FIG. 2 is a circuit diagram of a signal processing circuit.

FIG. 3 is a table showing constituent elements of a first suppressing device and a second suppressing device.

FIG. 4 is a diagram for describing operations of the first suppressing device including a suppressor.

FIG. 5 is a diagram for describing effects of the first suppressing device including the suppressor.

FIG. 6 is a diagram for describing operations of the first suppressing device including a varistor.

FIG. 7 is a diagram for describing effects of the first suppressing device including the varistor.

FIG. 8 is a circuit diagram of the first suppressing device including a capacitor.

FIG. 9 is a diagram for describing operations of the second suppressing device including a Zener diode.

FIG. 10 is a diagram for describing operations of the second suppressing device including a diode clamping circuit.

### DETAILED DESCRIPTION OF PREFERRED EMBODIMENTS

First, embodiments of this disclosure will be listed and described. At least some of the embodiments described below may be combined as appropriate.

### First Aspect

In accordance with a first aspect, a receiving apparatus according to one aspect of the present disclosure that receives a differential signal represented by a voltage difference between two signals that propagate through two signal lines, the receiving apparatus including: a first suppressing circuit and a second suppressing circuit configured to suppress peak values of the two signals; a DC removing circuit configured to remove DC components of the two signals; and a noise removing circuit configured to remove common mode noise included in the two signals, wherein, on a propagation path of the two signals, the DC removing circuit and the noise removing circuit are disposed between the first and second suppressing circuits, the differential signal propagates to the first suppressing circuit and the second suppressing circuit in this order, the first suppressing circuit includes two first connection devices respectively connected at one end to the two signal lines, if the voltage of the signal lines is a first threshold voltage, a current flows through the respective first connection devices, the second suppressing circuit includes two second connection devices respectively connected at one end to the two signal lines, if the voltage of the signal lines is a second threshold voltage, a current flows through the respective second connection devices, and the second threshold voltage is less than the first threshold voltage.

In the first aspect, the differential signal is input to the first suppressing circuit and output from the second suppressing circuit. Two signals that propagate through the two signal lines are input to the first suppressing circuit where the peak values of the two signals are suppressed. When the DC removing circuit is disposed on the first suppressing circuit side, the two signals whose peak values have been suppressed are input to the DC removing circuit where the DC components of the two signals are removed. The two signals from which the DC components have been removed are input to the noise removing circuit where common mode noise is removed from the two signals. The two signals from which the common mode noise has been removed are input to the second suppressing circuit where the peak values of the two signals are suppressed. The peak values are suppressed twice, and thus the peak values of the two signals from which the DC components have been removed are reliably suppressed to small values.

Also, the second threshold voltage regarding the second suppressing circuit is less than the first threshold voltage regarding the first suppressing circuit. Thus, the peak values of the two signals from which the DC components have been removed are more reliably suppressed to small values.

### Second Aspect

In a second aspect, the receiving apparatus according to one aspect of the present disclosure, further including a terminal circuit configured to suppress reflection of the two signals, wherein the terminal circuit is disposed on the propagation path, between the first suppressing circuit and the noise removing circuit.

In the second aspect, the terminal circuit is disposed between the first suppressing circuit and the noise removing circuit. Thus, the application of a high voltage to the terminal circuit in addition to the application of a high voltage to the DC removing circuit and the noise removing circuit is prevented.

### Third Aspect

In a third aspect, the receiving apparatus according to one aspect of the present disclosure, the two first suppressing devices each include a suppressor or a varistor.

In a third aspect, a suppressor or a varistor is used as a constituent element of the first connection devices for suppressing the peak values of the signals.

### Fourth Aspect

In a fourth aspect, the receiving apparatus according to one aspect of the present disclosure, the two second connection devices each include a suppressor, a varistor, a Zener diode, or a diode clamping circuit.

In the above aspect, a suppressor, a varistor, a Zener diode, or a diode clamping circuit is used as a constituent element of the second connection devices for suppressing the peak values of the signals.

Specific examples of a communication system according to embodiments of the present disclosure are described below with reference to the drawings. Note that the present invention is not limited to these examples, but is indicated by the claims, and all changes that come within the meaning and range of equivalency of the claims are intended to be embraced therein.

### Communication System Configuration

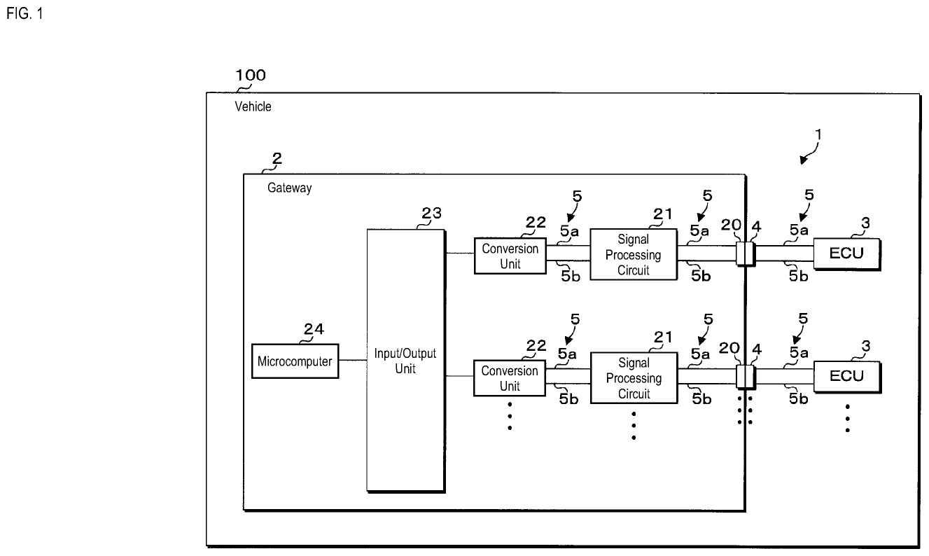

FIG. 1 is a block diagram showing the main configuration of a communication system 1 according to the present embodiment. The communication system 1 is preferably mounted in a vehicle 100. The communication system 1 includes a gateway 2 and ECUs 3. The ECUs 3 are respectively connected to connectors 4 via a communication line 5. Each communication line 5 includes two signal lines 5a and 5b. The two signal lines 5a and 5b are disposed twisted around one another or extend parallel to each other. The gateway 2 includes a plurality of connectors 20. The connectors 4 are respectively detachably connected to the connectors 20.

The gateway 2 and the ECUs 3 each function as a communication apparatus. In the communication system 1, two communication apparatuses are connected to one communication line 5. The gateway 2 transmits/receives differential signals to/from the ECUs 3. A differential signal is represented by a voltage difference between the two signals that propagate through the two signal lines 5a and 5b. In the communication system 1, BroadR-Reach is employed as the communication standard, for example. In this case, the gateway 2 and the ECUs 3 each chronologically change the voltages of two signal lines 5a and 5b to transmit a differential signal whose voltage difference is represented by three values. At this time, signals respectively propagate through the two signal lines 5a and 5b.

The gateway 2 and the ECUs 3 each receive a differential signal by detecting the voltage difference between the signal lines 5a and 5b. The gateway 2 and the ECUs 3 each function as a receiving apparatus. If differential signals are transmitted at the same time by the gateway 2 and an ECU 3 via one communication line 5, the gateway 2 subtracts the differential signal transmitted by the gateway 2 from the received differential signal. The gateway 2 treats the resultant differential signal as the differential signal transmitted by the ECU 3. The ECU 3 also subtracts the differential signal transmitted by the ECU 3 from the received differential signal. The ECU 3 treats the resultant differential signal as the differential signal transmitted by the gateway 2.

The gateway 2 relays communication between at least two of the ECUs 3. The gateway 2 receives a differential signal transmitted via the communication line 5 connected to one ECU 3. The gateway 2 converts the differential signal transmitted by the ECU 3 into a digital signal represented by a voltage whose reference potential is a ground potential. The gateway 2 selects, based on the resultant digital signal, at least one transmission destination from among the ECUs 3, and transmits a differential signal corresponding to the resultant digital signal to the one or more selected transmission destinations.

The ECU 3 receives the differential signal transmitted via the communication line 5 connected to the ECU 3. The ECU 3 converts the differential signal transmitted by the gateway 2 into a digital signal represented by a voltage whose reference potential is the ground potential. The ECU 3 is connected to an electrical device (not shown) mounted in the vehicle 100, for example. The ECU 3 controls operations of the electrical device by outputting a control signal to the electrical device. The ECU 3 determines, based on the resultant digital signal, the operation content of the electrical device, and outputs a control signal indicating the thus determined operation content to the electrical device. The electrical device performs operations that are based on the control signal input from the ECU 3.

The ECU 3 is connected to a sensor, for example. The sensor outputs a detection result to the ECU 3. The ECU 3 determines whether or not a differential signal is to be transmitted based on the detection result input from the sensor. If a determination is made to transmit a differential signal, the ECU 3 converts a digital signal indicating the transmission destination into a differential signal, and transmits the resultant differential signal to the gateway 2 via the communication line 5.

For example, one ECU 3 accepts an instruction to unlock a door of the vehicle 100. This ECU 3 transmits a differential signal instructing unlocking of the door to the gateway 2, with the ECU 3 connected to the motor for unlocking the door being the transmission destination. The gateway 2 transmits the differential signal instructing unlocking of the door to the ECU 3 connected to the motor for unlocking the door. This ECU 3 outputs a control signal instructing unlocking of the door to the motor. The motor unlocks the door.

### Configuration of Gateway 2

As shown in FIG. 1, the gateway 2 includes, in addition to the connectors 20, signal processing circuits 21, conversion units 22, an input/output unit 23, and a microcomputer 24. As described above, the connectors 20 are respectively detachably connected to the connectors 4. In the gateway 2, the connectors 20 are respectively connected to the signal processing circuits 21 by the communication lines 5. The signal processing circuits 21 are also respectively connected to the conversion units 22 by the communication lines 5. The conversion units 22 are connected to the input/output unit 23. The input/output unit 23 is also connected to the microcomputer 24.

The ECU 3 transmits a differential signal to the signal processing circuit 21 via the communication line 5. Thus, two signals propagate through the two signal lines 5a and 5b of the communication line 5. On the propagation paths of the two signals, the signal processing circuit 21 is disposed between the connector 20 and the conversion unit 22. When the signal processing circuit 21 receives a differential signal from the connector 20, the signal processing circuit 21 performs processing including processing for suppressing peak values of the two signals, processing for suppressing signal reflection of the two signals, processing for removing the DC components of the two signals, and processing for removing common mode noise from the two signals. The signal processing circuit 21 transmits the two signals to the conversion unit 22. The common mode noise is noise that propagates in the same direction through the signal lines 5a and 5b.

The conversion unit 22 transmits a differential signal to the ECU 3 via the signal processing circuit 21 and the connectors 20 and 4. Accordingly, two signals propagate through the two signal lines 5a and 5b of the communication line 5. The conversion unit 22 receives a differential signal by detecting the voltage difference between the two signal lines 5a and 5b of the communication line 5.

If the conversion unit 22 is transmitting a differential signal, the conversion unit 22 subtracts the transmitted differential signal from the received differential signal, and converts the resultant differential signal into a digital signal. If the conversion unit 22 is not transmitting a differential signal, the conversion unit 22 converts the received differential signal into a digital signal. The conversion unit 22 outputs the resultant digital signal to the input/output unit 23. The input/output unit 23 outputs the digital signals input from the conversion units 22 to the microcomputer 24. Based on the received digital signals, the microcomputer 24 selects one or more of the ECUs 3 to be a transmission destination for the received digital signals.

After selecting the transmission destination of the digital signals, the microcomputer 24 outputs the received digital signals to the input/output unit 23. The microcomputer 24, further, instructs the input/output unit 23 to output the digital signals input from the input/output unit 23 to the one or more conversion units 22 corresponding to the one or more selected ECUs 3. Upon receiving a digital signal from the input/output unit 23, the conversion unit 22 converts the digital signal input from the input/output unit 23 into a differential signal. Based on the digital signal input from the input/output unit 23, the conversion unit 22 chronologically changes the voltage difference between the two signal lines 5a and 5b. Thus, the digital signal input from the input/output unit 23 is converted into a differential signal, and the resultant differential signal is transmitted to the ECU 3 via the signal processing circuit 21 and the connectors 20 and 4.

When the signal processing circuit 21 receives a differential signal from the conversion unit 22, the signal processing circuit 21 performs processing including processing for suppressing the peak values of the two signals, processing for removing common mode noise from the two signals, and processing for removing the DC components from the two signals. The two signals propagate from the signal processing circuit 21 to the ECU 3 via the connectors 20 and 4. The ECU 3 receives the differential signal transmitted from the conversion unit 22.

### Configuration of Signal Processing Circuit 21

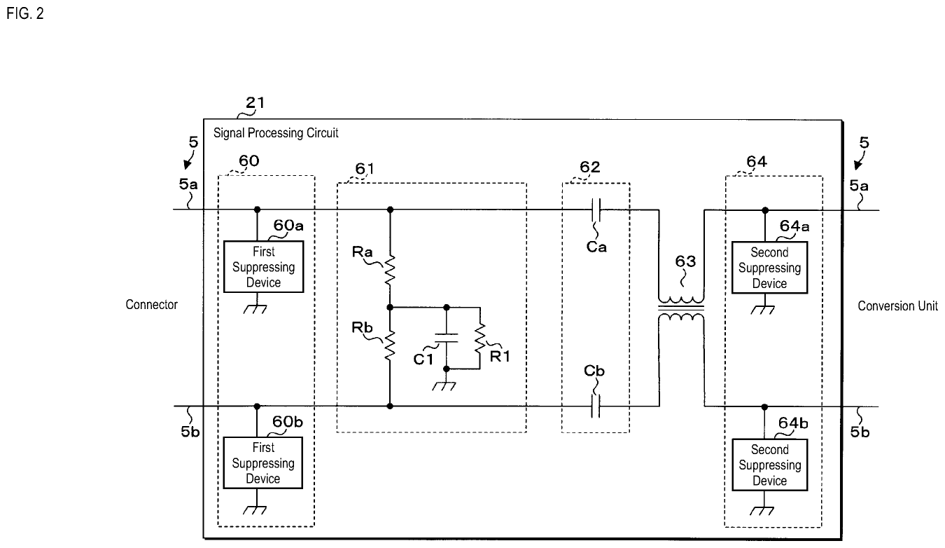

FIG. 2 is a circuit diagram of the signal processing circuit 21. The signal processing circuit 21 includes a first suppressing circuit 60, a terminal circuit 61, a DC removing circuit 62, a common mode choke coil 63, and a second suppressing circuit 64. On the propagation paths of the two signals that propagate through the two signal lines 5a and 5b, the terminal circuit 61, the DC removing circuit 62, and the common mode choke coil 63 are disposed between the first suppressing circuit 60 and the second suppressing circuit 64. The terminal circuit 61, the DC removing circuit 62, and the common mode choke coil 63 are arranged in this order in a direction from the first suppressing circuit 60 side toward the second suppressing circuit 64 side.

A description will be given regarding receipt of a differential signal that propagates from the connector 20 to the conversion unit 22. When a differential signal is received, the differential signal, that is, the two signals that propagate through the two signal lines 5a and 5b propagate from the connector 20 to the first suppressing circuit 60, the terminal circuit 61, the DC removing circuit 62, the common mode choke coil 63, and the second suppressing circuit 64 in this order. The first suppressing circuit 60 suppresses the peak values of the two signals input from the connector 20. The first suppressing circuit 60 includes two first suppressing devices 60a and 60b. The second suppressing devices 60a and 60b are respectively connected at one end to the two signal lines 5a and 5b. The other ends of the first suppressing devices 60a and 60b are grounded. The first suppressing devices 60a and 60b both function as a first connection device.

The first suppressing device 60a suppresses the peak value of the signal that propagates through the signal line 5a by either limiting the upper limit value and the lower limit value of the voltage of the signal line 5a whose reference potential is a ground potential or smoothing the voltage of the signal that propagates through the signal line 5a. Similarly, the first suppressing device 60b suppresses the peak value of the signal that propagates through the signal line 5b by either limiting the upper limit value and the lower limit value of the voltage of the signal line 5b whose reference potential is the ground potential or smoothing the voltage of the signal that propagates through the signal line 5b. The ground potential is the potential of the body of the vehicle 100, for example.

The first suppressing circuit 60 outputs the two signals whose peak values have been suppressed to the terminal circuit 61. The terminal circuit 61 suppresses reflection, to the connector 20 side, of the two signals that propagate through the two signal lines 5a and 5b. The terminal circuit 61 includes resistors R1, Ra, and Rb, and a capacitor C1.

The resistors Ra and Rb are respectively connected at one end to the signal lines 5a and 5b. The other ends of the resistors Ra and Rb are connected to one end of the resistor R1. The other end of the resistor R1 is grounded. The capacitor C1 is connected between two ends of the resistor R1. The resistance values of the resistors Ra, Rb, and R1 and the electrostatic capacitance of the capacitor C1 are set according to the characteristic impedance of the communication line 5. Thus, the terminal circuit 61 suppresses reflection of the two signals that propagate through the two signal lines 5a and 5b.

The two signals whose peak values have been suppressed by the first suppressing circuit 60 are input to the DC removing circuit 62 via the terminal circuit 61. The DC removing circuit 62 removes the DC components from the two signals received via the terminal circuit 61, and outputs the two signals whose DC components have been removed to the common mode choke coil 63. The DC removing circuit 62 includes two capacitors Ca and Cb. The capacitor Ca is disposed at an intermediate position of the signal line 5a. The capacitor Cb is disposed at an intermediate position of the signal line 5b. The capacitor Ca removes the DC component of the signal that propagates through the signal line 5a, and outputs a signal whose DC component has been removed. Similarly, the capacitor Cb removes the DC component of the signal that propagates through the signal line 5b, and outputs a signal whose DC component has been removed.

The common mode choke coil 63 removes common mode noise from the two signals input from the DC removing circuit 62. The common mode choke coil 63 functions as a noise removing circuit. The common mode choke coil 63 has two coils and an annular core. The two coils are wound around the annular core. One coil is disposed at an intermediate position of the signal line 5a. The other coil is disposed at an intermediate position of the signal line 5b.

The common mode choke coil 63 has high impedance to the common mode voltages that propagate in the same direction through the two signal lines 5a and 5b. Thus, the common mode noise does not pass through the common mode choke coil 63. The common mode choke coil 63 has low impedance to voltages of differential-mode voltages that propagate in different directions through the two signal lines 5a and 5b. Thus, the differential-mode component included in a differential signal passes through the common mode choke coil 63. As a result, the common mode choke coil 63 removes the common mode noise included in the differential signal, that is, the two signals that propagate through the two signal lines 5a and 5b. The common mode choke coil 63 outputs two signals from which common mode noise has been removed, to the second suppressing circuit 64.

The second suppressing circuit 64 suppresses the peak values of the two signals that propagate from the common mode choke coil 63. The second suppressing circuit 64 includes two second suppressing devices 64a and 64b. One ends of the two second suppressing devices 64a and 64b are correspondingly connected to the two signal lines 5a and 5b. The other ends of the two second suppressing devices 64a and 64b are grounded. The second suppressing devices 64a and 64b both function as a second connection device.

The second suppressing device 64a suppresses the peak value of the signal that propagates through the signal line 5a by either limiting the upper limit value and the lower limit value of the voltage of the signal line 5a whose reference potential is the ground potential or smoothing the voltage of the signal that propagates through the signal line 5a. Similarly, the second suppressing device 64b suppresses the peak value of the signal that propagates through the signal line 5b by either limiting the upper limit value and the lower limit value of the voltage of the signal line 5b whose reference potential is the ground potential or smoothing the voltage of the signal that propagates through the signal line 5b. The second suppressing circuit 64 inputs the two signals whose peak values have been suppressed to the conversion unit 22.

Next, transmission of a differential signal that propagates from the conversion unit 22 to the connector 20 will be described. When a differential signal is transmitted, the differential signal, that is, the two signals that propagate through the two signal lines 5a and 5b propagate from the conversion unit 22 to the second suppressing circuit 64, the common mode choke coil 63, the DC removing circuit 62, the terminal circuit 61, and the first suppressing circuit 60 in this order. The second suppressing circuit 64 suppresses the peak values of the two signals input from the conversion unit 22 in a similar fashion to when the second suppressing circuit 64 receives two signals from the common mode choke coil 63. The second suppressing circuit 64 outputs the two signals whose peak values have been suppressed to the common mode choke coil 63.

The common mode choke coil 63 removes common mode noise from the two signals input from the second suppressing circuit 64 in a similar fashion to when the common mode choke coil 63 receives signals from the DC removing circuit 62. The common mode choke coil 63 outputs the two signals from which common mode noise has been removed to the DC removing circuit 62.

The DC removing circuit 62 removes DC components from the two signals input from the common mode choke coil 63 in a similar fashion to when the DC removing circuit 62 receives two signals from the first suppressing circuit 60 via the terminal circuit 61. The DC removing circuit 62 outputs the two signals from which the DC components have been removed to the first suppressing circuit 60 via the terminal circuit 61.

The first suppressing circuit 60 suppresses the peak values of the two signals received from the DC removing circuit 62 via the terminal circuit 61 in a similar fashion to when the first suppressing circuit 60 receives two signals from the connector 20. The first suppressing circuit 60 outputs the two signals whose peak values have been suppressed to the connector 20.

Note that the ECU 3 may include a signal processing circuit 21, a conversion unit 22, and a microcomputer 24, similarly to the gateway 2. In this case, the connector 4 and the signal processing circuit 21 are connected by the communication line 5, and the signal processing circuit 21 and the conversion unit 22 are connected by the communication line 5. The conversion unit 22 is connected to the microcomputer 24. The conversion unit 22 converts the differential signal input from the signal processing circuit 21 into a digital signal, and outputs the resultant digital signal to the microcomputer 24. The microcomputer 24 outputs the digital signal to the conversion unit 22. The conversion unit 22 converts the digital signal input from the microcomputer 24 into a differential signal, and outputs the resultant differential signal to the signal processing circuit 21. In the signal processing circuit 21 in the ECU 3, similarly to the signal processing circuit 21 of the gateway 2, the first suppressing circuit 60, the terminal circuit 61, the DC removing circuit 62, the common mode choke coil 63, and the second suppressing circuit 64 are arranged in this order on the propagation paths of the two signals in a direction from the connector 4 side toward the conversion unit 22 side.

### Constituent Elements of First Suppressing Device 60a and Second Suppressing Device 64a

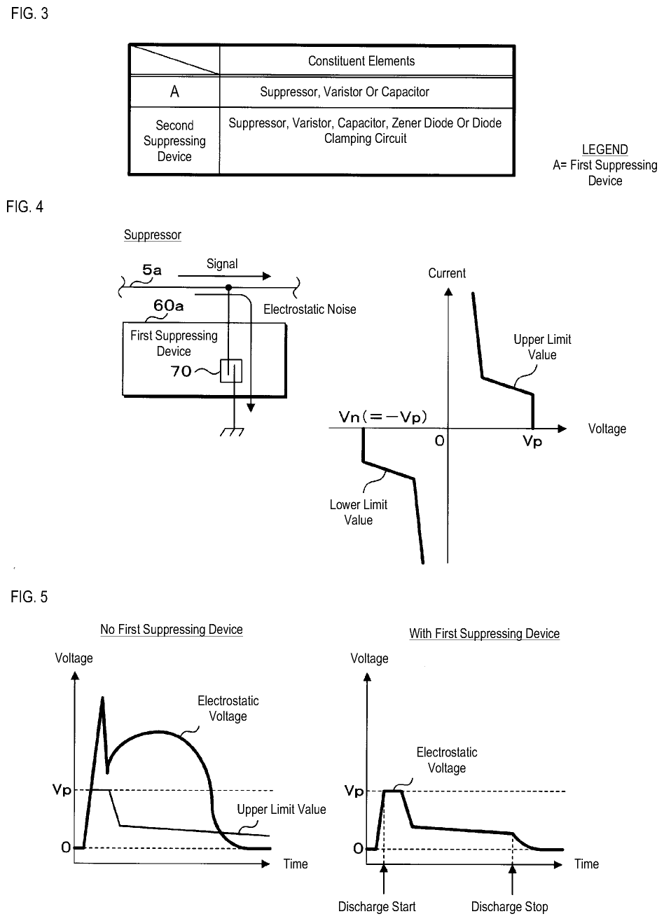

FIG. 3 is a table showing the constituent elements of the first suppressing device 60a and the second suppressing device 64a. Examples of the constituent elements of the first suppressing device 60a include a suppressor, a varistor, and a capacitor. Examples of the constituent elements of the first suppressing device 60b include constituent elements similar to those of the first suppressing device 60a. It is preferable that the first suppressing devices 60a and 60b have the same types of constituent elements. For example, if the first suppressing device 60a is provided with a suppressor, it is preferable that the first suppressing device 60b is also provided with a suppressor.

Examples of constituent elements of the second suppressing device 64a include a suppressor, a varistor, a Zener diode, a diode clamping circuit, and a capacitor. Examples of constituent elements of the second suppressing device 64b include similar constituent elements to those of the second suppressing device 64b. It is preferable that, similarly to the two first suppressing devise 60a and 60b, the two second suppressing devices 64a and 64b have the same type of constituent elements.

### Description of First Suppressing Device 60a Including Suppressor

FIG. 4 is a diagram for describing operations of the first suppressing device 60a that includes a suppressor 70. The configuration of the first suppressing device 60a including the suppressor 70 is shown on the left side of FIG. 4. One end of the suppressor 70 is connected to the signal line 5a. The other end of the suppressor 70 is grounded. The current-voltage characteristics of the suppressor 70 are shown on the right side of FIG. 4. The voltage shown in the current-voltage characteristics is the voltage of the signal line 5a whose reference potential is a ground potential. The current shown in the current-voltage characteristics is the current that flows through the suppressor 70. A current that flows from the signal line 5a via the suppressor 70 is a positive current. A current that flows to the signal line 5a via the suppressor 70 is a negative current.

When there is static electricity on the signal line 5a or in the vicinity of the signal line 5a, noise is superimposed onto the signal that propagates through the signal line 5a. Below, noise regarding static electricity is referred to as electrostatic noise. In the voltage waveform of the signal onto which electrostatic noise is superimposed, the voltage of the signal temporarily increases to a positive voltage with a large absolute value, or decreases to a negative voltage with a large absolute value.

In the suppressor 70, two conductors oppose each other across an air layer. One conductor is connected to the signal line 5a. The other conductor is grounded. When the voltage of the signal line 5a, that is, the voltage applied to the suppressor 70 exceeds a predetermined negative voltage Vn, and is less than a predetermined positive voltage Vp, no current flows through the suppressor 70. In a state where no current is flowing through the suppressor 70, if the voltage of the signal line 5a whose reference potential is a ground potential, that is, the voltage applied to the suppressor 70 is the positive voltage Vp, electricity is discharged between the two conductors. As a result, a positive current flows through the suppressor 70, and an increase in the absolute value of the voltage of the signal line 5a whose reference potential is the ground potential is suppressed. The positive voltage Vp corresponds to a first threshold voltage.

Also, in the state where no current is flowing through the suppressor 70, if the voltage of the signal line 5a whose reference potential is the ground potential is the negative voltage Vn, electricity is discharged between the two conductors. As a result, a negative current flows through the suppressor 70, and an increase in the absolute value of the voltage of the signal line 5a whose reference potential is the ground potential is suppressed. The negative voltage Vn also corresponds to the first threshold voltage. The positive voltage Vp substantially matches the absolute value of the negative voltage Vn. As a result of a positive current and a negative current flowing through the suppressor 70, electrostatic noise propagates through the suppressor 70, and electrostatic noise is removed from the signal that propagates through the signal line 5a.

When a positive current flows through the suppressor 70, the voltage of the signal line 5a is kept at the upper limit value. As shown with the current-voltage characteristics in FIG. 4, when a positive current flows through the suppressor 70, the positive current increases, and the upper limit value fluctuates. First, when the positive current is small, the upper limit value is kept at a predetermined value. Then, as the positive current increases, that is, as time passes, the upper limit value rapidly decreases. After the upper limit value has decreased rapidly, the upper limit value gently falls as the positive current increases. When the voltage of the signal line 5a is smaller than the upper limit value, the current flowing through the suppressor 70 decreases to zero (A). Once the current is zero (A), no current flows through the suppressor 70 until the voltage of the signal line 5a whose reference potential is the ground potential is the positive voltage Vp or the negative voltage Vn.

Similarly, when a negative current flows through the suppressor 70, the voltage of the signal line 5a is kept at the lower limit value. When the negative current flows through the suppressor 70, the negative current decreases and the lower limit value fluctuates. First, when the absolute value of the negative current is small, the lower limit value is kept at a predetermined value. Then, as the negative current decreases, that is, as time passes, the lower limit value rapidly increases. After the lower limit value has rapidly increased, the lower limit value gently increases as the negative current decreases. If the voltage across the two ends of the suppressor 70 exceeds the lower limit value as a result of the absolute value of the voltage across the two ends of the suppressor 70 being reduced, the current flowing through the suppressor 70 decreases to zero (A). Once the current is zero (A), no current flows through the suppressor 70 until the voltage of the signal line 5a whose reference potential is the ground potential is the positive voltage Vp or the negative voltage Vn.

FIG. 5 is a diagram for describing effects of the first suppressing device 60a including the suppressor 70. Below, the voltage of the signal line 5a when there is static electricity on the signal line 5a is referred to as the “electrostatic voltage”. The waveform of the electrostatic voltage when the first suppressing device 60a is not installed is shown with a thick solid line on the left side of FIG. 5. Furthermore, transition of the upper limit value of the voltage when the first suppressing device 60a is installed is shown with a thin solid line on the left side of FIG. 5. The waveform of the electrostatic voltage when the first suppressing device 60a is installed is shown on the right side of FIG. 5. The electrostatic voltage shown in FIG. 5 is a positive voltage.

When no first suppressing device 60a is installed, the electrostatic voltage increases rapidly and then decreases rapidly. After the electrostatic voltage has rapidly decreased, the electrostatic voltage gently increases. Then, the electrostatic voltage gently decreases to zero (V).

When the first suppressing device 60a is mounted, and the electrostatic voltage is the positive voltage Vp, discharge is started in the suppressor 70, and the electrostatic voltage is limited to the positive voltage Vp. Then, the electrostatic voltage transitions similarly to the upper limit value until the electrostatic voltage falls below the upper limit value. When the electrostatic voltage is smaller than the upper limit value, discharging in the suppressor 70 is stopped, and the electrostatic voltage decreases from the upper limit value to zero (V).

When the electrostatic voltage is a negative voltage, the suppressor 70 operates in a similar fashion to when the electrostatic voltage is a positive voltage. Thus, when the first suppressing device 60a is mounted, and the electrostatic voltage is the negative voltage Vn, discharging is started in the suppressor 70, and the electrostatic voltage is limited to the negative voltage Vn. Then, the electrostatic voltage transitions similarly to the lower limit value until the electrostatic voltage exceeds the lower limit value. When the electrostatic voltage is greater than the lower limit value, discharging in the suppressor 70 is stopped, and the electrostatic voltage increases to zero (V) from the lower limit value.

As described above, when the voltage of the signal line 5a is the positive voltage Vp or the negative voltage Vn, a current flows through the first suppressing device 60a. The first suppressing device 60a including the suppressor 70 suppresses the voltage of the signal line 5a, that is, the peak value of the signal that propagates through the signal line 5a to the upper limit value or the lower limit value of the current-voltage characteristics. Also, no current flows through the first suppressing device 60a, that is, the suppressor 70 until the voltage of the signal line 5a is the positive voltage Vp or the negative voltage Vn. Thus, the absolute value of the peak value of the signal that propagates through the signal line 5a is not suppressed to a value smaller than the absolute value of the positive voltage Vp or the absolute value of the negative voltage Vn.

### First Suppressing Device 60b and Second Suppressing Devices 64a and 64b Including Suppressor 70

If the first suppressing device 60a is provided with the suppressor 70, it is preferable that the first suppressing device 60b is also provided with the suppressor 70. The first suppressing device 60b whose suppressor 70 is connected to the signal line 5b operates in a similar fashion to the first suppressing device 60a including the suppressor 70. When the voltage of the signal line 5b is the positive voltage Vp or the negative voltage Vn, a current flows through the first suppressing device 60b.

As shown in FIG. 3, the second suppressing devices 64a and 64b may each include a suppressor 70. The second suppressing device 64a whose suppressor 70 is connected to the signal line 5a and the second suppressing device 64b whose suppressor 70 is connected to the signal line 5b both operate similarly to the first suppressing device 60a including the suppressor 70. When the voltages of the two signal lines 5a and 5b are the positive voltage Vp or the negative voltage Vn, a current flows through the second suppressing devices 64a and 64b, respectively. The positive voltage Vp and the negative voltage Vn of the second suppressing devices 64a and 64b correspond to a second threshold voltage.

### Description of First Suppressing Device 60a Including Varistor

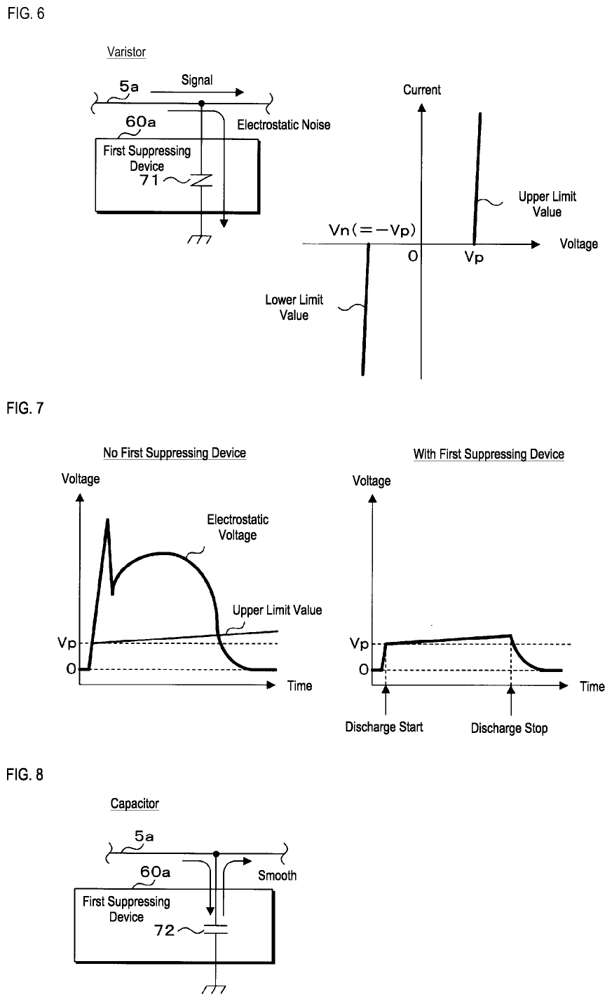

FIG. 6 is a diagram for describing operations of the first suppressing device 60a including a varistor 71. The configuration of the first suppressing device 60a including the varistor 71 is shown on the left side of FIG. 6. One end of the varistor 71 is connected to the signal line 5a. The other end of the varistor 71 is grounded. The current-voltage characteristics of the varistor 71 are shown on the right side of FIG. 6. The voltage shown in the current-voltage characteristics is the voltage of the signal line 5a whose reference potential is the ground potential. The current shown in the current-voltage characteristics is a current that flows through the varistor 71. A current that flows from the signal line 5a via the varistor 71 is a positive current. A current that flows to the signal line 5a via the varistor 71 is a negative current.

When the voltage (absolute value) between two ends of the barrister 71 is less than a predetermined value, no current flows through the varistor 71. When the voltage (absolute value) between two ends of the varistor 71 is greater than or equal to a predetermined value, the resistance value of the varistor 71 decreases, and a current flows through the varistor 71. Thus, when the voltage of the signal line 5a whose reference potential is the ground potential is greater than the predetermined negative voltage Vn, and is less than the predetermined positive voltage Vp, no current flows through the varistor 71. When the voltage of the signal line 5a whose reference potential is the ground potential is the positive voltage Vp, the resistance value of the varistor 71 decreases, and a positive current flows therethrough. An increase in the voltage of the signal line 5a whose reference potential is the ground potential is suppressed.

When the voltage of the signal line 5a whose reference potential is the ground potential is the negative voltage Vn, a negative current flows through the varistor 71. An increase in the absolute value of the voltage of the signal line 5a whose reference potential is the ground potential is suppressed. The absolute values of the positive voltage Vp and the negative voltage Vn are substantially the same. The positive voltage Vp substantially coincides with the absolute value of the negative voltage Vn.

As a result of a positive current and a negative current flowing through the varistor 71, electrostatic noise propagates through the varistor 71, and electrostatic noise is removed from the signal that propagates through the signal line 5a.

When a positive current flows through the varistor 71, the voltage of the signal line 5a is kept at the upper limit value. As shown in the current-voltage characteristics in FIG. 6, when a positive current flows through the varistor 71, the positive current increases, and the upper limit value gently increases as the positive current increases. When the voltage of the signal line 5a is smaller than the upper limit value, the resistance value of the varistor 71 increases, and the current flowing through the varistor 71 decreases to zero (A). After the current has decreased to zero (A), no current flows through the varistor 71 until the voltage of the signal line 5a is the positive voltage Vp or the negative voltage Vn.

Similarly, when a negative current flows through the varistor 71, the voltage of the signal line 5a is kept at the lower limit value. As shown in the current-voltage characteristics shown in FIG. 6, when a negative current flows through the varistor 71, the negative current decreases, and the lower limit value gently decreases as the negative current decreases. When the voltage of the signal line 5a exceeds the lower limit value, the resistance value of the varistor 71 increases, and the current flowing through the varistor 71 increases to zero (A). After the current has increased to zero (A), no current flows through the varistor 71 until the voltage of the signal line 5a is the positive voltage Vp or the negative voltage Vn.

FIG. 7 is a diagram for describing effects of the first suppressing device 60a including the varistor 71. The waveform of the electrostatic voltage when no first suppressing device 60a is installed is shown with a thick solid line on the left side of FIG. 7. The transition of the upper limit value when the first suppressing device 60a is installed is shown with a thin solid line on the left side of FIG. 7 as well. The waveform of the electrostatic voltage when the first suppressing device 60a is installed is shown on the right side of FIG. 7. The electrostatic voltage shown in FIG. 7 is a positive voltage.

The transition of the electrostatic voltage shown on the left side of FIG. 7 is the same as the transition of the electrostatic voltage shown on the left side of FIG. 5, and is as described above. When the first suppressing device 60a is installed, and the electrostatic voltage is the positive voltage Vp, the resistance value of the varistor 71 decreases, a current flows from the signal line 5a via the varistor 71, and the electrostatic voltage is limited to the positive voltage Vp. Then, the electrostatic voltage transitions similarly to the upper limit value, until the electrostatic voltage falls below the upper limit value. When the electrostatic voltage is smaller than the upper limit value, the resistance value of the varistor 71 increases, and passage of a current through the varistor 71 is stopped. Thereafter, the electrostatic voltage decreases from the upper limit value to zero (V).

When the electrostatic voltage is a negative voltage, the varistor 71 operates similarly to when the electrostatic voltage is a positive voltage. Accordingly, when the first suppressing device 60a is installed, and the electrostatic voltage is the negative voltage Vn, the resistance value of the varistor 71 decreases, a current flows through the varistor 71, and the electrostatic voltage is limited to the negative voltage Vn. Then, the electrostatic voltage transitions similarly to the lower limit value, until the electrostatic voltage exceeds the lower limit value. When the electrostatic voltage is greater than the lower limit value, the resistance value of the varistor 71 increases, and the passage of a current through the varistor 71 is stopped. Thereafter, the electrostatic voltage increases from the lower limit value to zero (V).

As described above, when the voltage of the signal line 5a is the positive voltage Vp or the negative voltage Vn, a current flows through the first suppressing device 60a. An increase in the voltage of the signal line 5b is suppressed. The first suppressing device 60a including the varistor 71 suppresses the voltage of the signal line 5a, that is, the peak value of the signal that propagates through the signal line 5a to the upper limit value or the lower limit value of the current-voltage characteristics. Also, no current flows through the first suppressing device 60a, that is, the suppressor 70 until the voltage of the signal line 5a is the positive voltage Vp or the negative voltage Vn. Thus, the absolute value of the peak value of the signal that propagates through the signal line 5a is not suppressed to a value smaller than the absolute values of the positive voltage Vp and the negative voltage Vn.

### First Suppressing Device 60b and Second Suppressing Devices 64a and 64b Including Varistor 71

If the first suppressing device 60a is provided with the varistor 71, it is preferable that the first suppressing device 60b is also provided with the varistor 71. The first suppressing device 60b whose varistor 71 is connected to the signal line 5b operates in a similar fashion to the first suppressing device 60a including the varistor 71. When the voltage of the signal line 5b is the positive voltage Vp or the negative voltage Vn, a current flows through the first suppressing device 60b.

As shown in FIG. 3, the second suppressing devices 64a and 64b may each be provided with a varistor 71. The second suppressing device 64a whose varistor 71 is connected to the signal line 5a and the second suppressing device 64b whose varistor 71 is connected to the signal line 5b both operate in a similar fashion to the first suppressing device 60a including the varistor 71. When the voltages of the two signal lines 5a and 5b are the positive voltage Vp or the negative voltage Vn, a current flows through the second suppressing devices 64a and 64b.

### Description of First Suppressing Device 60a Including Capacitor

FIG. 8 is a circuit diagram of the first suppressing device 60a including a capacitor 72. One end of the capacitor 72 is connected to the signal line 5a. The other end of the capacitor 72 is grounded. The capacitor 72 smooths the voltage of the signal line 5a whose reference potential is the ground potential. As described above, when noise is superimposed onto the signal that propagates through the signal line 5a, the voltage of the signal temporarily increases to a positive voltage with a large absolute value, or decreases to a negative voltage with a large absolute value. The capacitor 72 smooths the voltage of the signal line 5a, and thus the voltage of the signal line 5a, that is, the peak value of the signal that propagates through the signal line 5a is suppressed.

### First Suppressing Device 60b and Second Suppressing Devices 64a and 64b Including Capacitor 72

When the first suppressing device 60a is provided with the capacitor 72, it is preferable that the first suppressing device 60b is also provided with the capacitor 72. The first suppressing device 60b whose capacitor 72 is connected to the signal line 5b operates in a similar fashion to the first suppressing device 60a including the capacitor 72, and smooths the voltage of the signal line 5b. The peak value of the voltage of the signal line 5b is suppressed. As shown in FIG. 3, the second suppressing devices 64a and 64b may each be provided with a capacitor 72. The second suppressing device 64a whose capacitor 72 is connected to the signal line 5a and the second suppressing device 64b whose capacitor 72 is connected to the signal line 5b both operate similarly to the first suppressing device 60a that includes the capacitor 72. The two second suppressing devices 64a and 64b respectively smooth the voltages of the two signal lines 5a and 5b. The peak values of the voltages of the signal lines 5a and 5b are suppressed. When each of the second suppressing devices 64a and 64b are provided with the capacitor 72, the capacitors 72 each function as a second capacitor.

### Description of Second Suppressing Device 64a Including Zener Diode

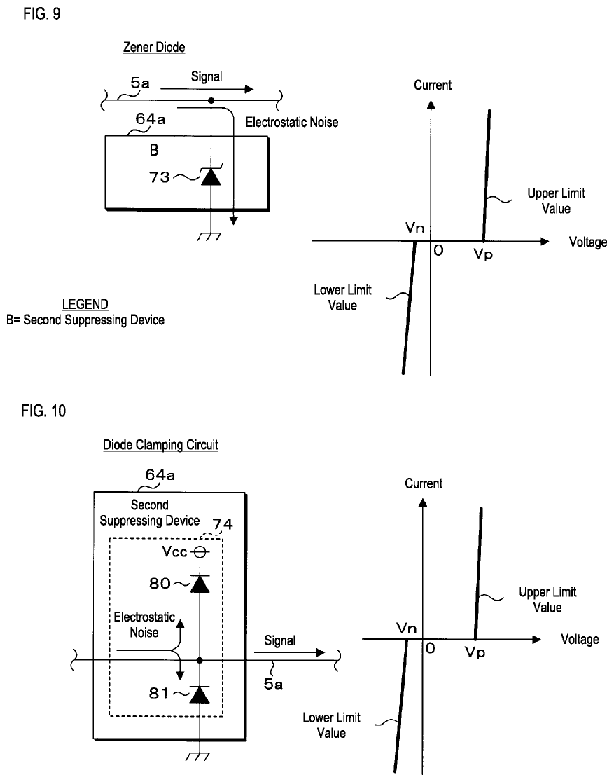

FIG. 9 is a diagram for describing operations of the second suppressing device 64a including a Zener diode 73. The circuit of the second suppressing device 64b including the Zener diode 73 is shown on the left side of FIG. 9. The cathode of the Zener diode 73 is connected to the signal line 5a. The anode of the Zener diode 73 is grounded. The current-voltage characteristics of the Zener diode 73 are shown on the right side of FIG. 9. The voltage shown in the current-voltage characteristics is the voltage of the signal line 5a whose reference potential is the ground potential. The current shown in the current-voltage characteristics is a current that flows through the Zener diode 73. The current that flows from signal line 5a and through the cathode and the anode of the Zener diode 73 in this order is a positive current. The current that flows to the anode and the cathode of the Zener diode 73 and to the signal line 5a in this order is a negative current.

When the voltage of the signal line 5a exceeds the predetermined negative voltage Vn, and is less than the predetermined positive voltage Vp, no current flows through the Zener diode 73. When the voltage of the signal line 5a is the positive voltage Vp, a positive current flows through the Zener diode 73. An increase in the absolute value of the voltage of the signal line 5a whose reference potential is the ground potential is suppressed. The positive voltage Vp is a breakdown voltage of the Zener diode 73.

When the voltage of the signal line 5a is the negative voltage Vn, a negative current flows through the Zener diode 73. An increase in the absolute value of the voltage of the signal line 5a whose reference potential is the ground potential is suppressed. The absolute value of the negative voltage Vn is the forward voltage of the Zener diode 73, and is 0.6 V, for example.

As a result of the positive and negative currents flowing through the Zener diode 73, electrostatic noise propagates through the Zener diode 73, and the electrostatic noise is removed from the signal that propagates through the signal line 5a.

The current-voltage characteristics of the Zener diode 73 are similar to the current-voltage characteristics of the varistor 71. When a positive current flows through the Zener diode 73, the voltage of the signal line 5a is kept at the upper limit value. As shown in the current-voltage characteristics in FIG. 9, when the positive current flows through the Zener diode 73, the positive current increases, and the upper limit value gently increases as the positive current increases. When the voltage of the signal line 5a falls below the upper limit value, the current flowing through the Zener diode 73 falls to zero (A). After the current has fallen to zero (A), no current flows through the Zener diode 73 until the voltage of the signal line 5a is the positive voltage Vp or the negative voltage Vn.

Similarly, when a negative current flows through the Zener diode 73, the voltage of the signal line 5a is kept at the lower limit value. As shown in the current-voltage characteristics in FIG. 9, when a negative current flows through the Zener diode 73, the negative current falls, and the lower limit value gently decreases as the negative current falls. When the voltage of the signal line 5a exceeds the lower limit value, the current flowing through the Zener diode 73 increases to zero (A). After the current has increased to zero (A), no current flows through the Zener diode 73 until the voltage of the signal line 5a is the positive voltage Vp or the negative voltage Vn.

The effects of the second suppressing device 64a including the Zener diode 73 are similar to the effects of the first suppressing device 60a including the varistor 71 (see FIG. 7). When the second suppressing device 64a is installed, and the electrostatic voltage is the positive voltage Vp, a current flows from the signal line 5a to the cathode and the anode of the Zener diode 73 in this order, and the electrostatic voltage is limited to the positive voltage Vp. Then, the electrostatic voltage transitions similarly to the upper limit value until the electrostatic voltage falls below the upper limit value. When the electrostatic voltage falls below the upper limit value, passage of a current through the Zener diode 73 is stopped. Thereafter, the electrostatic voltage decreases from the upper limit value to zero (V).

When the second suppressing device 64a is installed, and the electrostatic voltage is the negative voltage Vn, a current flows through the Zener diode 73, and the electrostatic voltage is limited to the negative voltage Vn. Then, the electrostatic voltage transitions similarly to the lower limit value, until the electrostatic voltage exceeds the lower limit value. When the electrostatic voltage exceeds the lower limit value, passage of a current though the Zener diode 73 is stopped. Thereafter, the electrostatic voltage increases from the lower limit value to zero (V).

As described above, when the voltage of the signal line 5a is the positive voltage Vp or the negative voltage Vn, a current flows through the second suppressing device 64a. The second suppressing device 64a including the Zener diode 73 suppresses the voltage of the signal line 5a, that is, the peak value of the signal that propagates through the signal line 5a to the upper limit value or the lower limit value of the current-voltage characteristics. Also, no current flows through the second suppressing device 64a, that is, the Zener diode 73 until the voltage of the signal line 5a is the positive voltage Vp or the negative voltage Vn. Thus, the absolute value of the peak value of the signal that propagates through the signal line 5a is not suppressed to a value smaller than the absolute values of the positive voltage Vp or the negative voltage Vn.

### Second Suppressing Device 64b Including Zener Diode 73

If the second suppressing device 64a is provided with the Zener diode 73, it is preferable that the second suppressing device 64b is also provided with the Zener diode 73. The second suppressing device 64b whose Zener diode 73 is connected to the signal line 5b operates in a similar fashion to the second suppressing device 64a including the Zener diode 73. When the voltage of the signal line 5b is the positive voltage Vp or the negative voltage Vn, a current flows through the second suppressing device 64b. An increase in the absolute value of the voltage of the signal line 5b is suppressed.

### Description of Second Suppressing Device 64a Including Diode Clamping Circuit

FIG. 10 is a diagram for describing operations of the second suppressing device 64b including a diode clamping circuit 74. The circuit of the second suppressing device 64b including the diode clamping circuit 74 is shown on the left side of FIG. 10. The diode clamping circuit 74 includes two diodes 80 and 81. A predetermined voltage Vcc is applied to the cathode of the diode 80. The anode of the diode 80 is connected to the signal line 5a. The cathode of the diode 81 is connected to the signal line 5a. The anode of the diode 81 is grounded.

The current-voltage characteristics of the diode clamping circuit 74 are shown on the right side of FIG. 10. The voltage shown in the current-voltage characteristics is the voltage of the signal line 5a whose reference potential is the ground potential. A current shown in the current-voltage characteristics is the current that flows through either one of the diodes 80 and 81. The current that flows from the signal line 5a to the anode and cathode of the diode 80 in this order is a positive current. A current that flows to the anode and the cathode of the diode 81 and to the signal line 5a in this order is a negative current.

When the voltage of the signal line 5a exceeds the predetermined negative voltage Vn and is less than the predetermined positive voltage Vp, no current flows through the diodes 80 and 81. When the voltage of the signal line 5a is the positive voltage Vp, a positive current flows through the diode clamping circuit 74. An increase in the absolute value of the voltage of the signal line 5a whose reference potential is the ground potential is suppressed. The positive voltage Vp is a value obtained by adding the forward voltage of the diode 80 to a predetermined voltage Vcc.

When the voltage of the signal line 5a is the negative voltage Vn, a negative current flows through the diode clamping circuit 74. An increase in the absolute value of the voltage of the signal line 5a whose reference potential is the ground potential is suppressed. The absolute value of the negative voltage Vn is the forward voltage of the diode 81 and is 0.6 V, for example.

As a result of a positive current and a negative current flowing through the diode clamping circuit 74, electrostatic noise propagates through the diode 80 or the diode 81, and the electrostatic noise is removed from the signal that propagates through the signal line 5a.

The current-voltage characteristics of the diode clamping circuit 74 are similar to the current-voltage characteristics of the varistor 71. When a positive current flows through the diode 80 of the diode clamping circuit 74, the voltage of the signal line 5a is kept at the upper limit value. As shown in the current-voltage characteristics of FIG. 10, while the positive current flows through the diode clamping circuit 74, the positive current increases, and the upper limit value gently increases as the positive current increases. When the voltage of the signal line 5a falls below the upper limit value, passage of a current through the diode 80 is stopped. After passage of the current through the diode 80 is stopped, no current flows through either one of the diodes 80 and 81 until the voltage of the signal line 5a is the positive voltage Vp or the negative voltage Vn.

Similarly, when a negative current flows through the diode 81 of the diode clamping circuit 74, the voltage of the signal line 5a is kept at the lower limit value. As shown in the current-voltage characteristics in FIG. 10, when a negative current flows through the diode clamping circuit 74, the negative current decreases, and the lower limit value gently decreases as the negative current falls. When the voltage of the signal line 5a exceeds the lower limit value, passage of a current through the diode 81 is stopped. After the passage of the current through the diode 81 is stopped, no current flows through either one of the diodes 80 and 81 until the voltage of the signal line 5a is the positive voltage Vp and the negative voltage Vn.

Effects of the second suppressing device 64a including the diode clamping circuit 74 are similar to effects of the first suppressing device 60a including the varistor 71 (see FIG. 7). When the second suppressing device 64a is installed, and the electrostatic voltage is the positive voltage Vp, a current flows from the signal line 5a to the anode and the cathode of the diode 80 in this order, and the electrostatic voltage is limited to the positive voltage Vp. Then, the electrostatic voltage transitions similarly to the upper limit value until the electrostatic voltage falls below the upper limit value. When the electrostatic voltage falls below the upper limit value, the passage of a current through the diode 81 is stopped. Thereafter, the electrostatic voltage falls from the upper limit value to zero (V).

When the second suppressing device 64a is installed, and the electrostatic voltage is the negative voltage Vn, a current flows through the diode 81, and the electrostatic voltage is limited to the negative voltage Vn. Then, the electrostatic voltage transitions similarly to the lower limit value, until the electrostatic voltage exceeds the lower limit value. When the electrostatic voltage exceeds the lower limit value, passage of a current through the diode 81 is stopped. Thereafter, the electrostatic voltage increases from the lower limit value to zero (V).

As described above, when the voltage of the signal line 5a is the positive voltage Vp or the negative voltage Vn, a current flows through the second suppressing device 64a. The second suppressing device 64a including the diode clamping circuit 74 suppresses the voltage of the signal line 5a, that is, the peak value of the signal that propagates through the signal line 5a to the upper limit value or the lower limit value of the current-voltage characteristics. Also, no current flows through the first suppressing device 60a, that is, the diode 80 until the voltage of the signal line 5a is the positive voltage Vp or the negative voltage Vn. Thus, the absolute value of the peak value of the signal that propagates through the signal line 5a is not suppressed to a value smaller than the absolute value of the positive voltage Vp or the negative voltage Vn.

### Second Suppressing Device 64b Including Diode Clamping Circuit 74

If the second suppressing device 64a is provided with the diode clamping circuit 74, it is preferable that the second suppressing device 64b is also provided with the diode clamping circuit 74. The second suppressing device 64b whose diode clamping circuit 74 is connected to the signal line 5b operates in a similar fashion to the second suppressing device 64a including the diode clamping circuit 74. When the voltage of the signal line 5b is the positive voltage Vp or the negative voltage Vn, a current flows through the second suppressing device 64b. An increase in the absolute value of the voltage of the signal line 5b is suppressed.

### Regarding Absolute Values of Positive Voltage Vp and Negative Voltage Vn

It is preferable that, in the gateway 2, there is little noise in the signal input to the converting unit 22 via the signal processing circuit 21. However, communication standards stipulate that suppressing the absolute values of the peak values of signals input to the first suppressing circuit 60 to a value smaller than a predetermined value, for example, 100 V, is prohibited. Thus, in a case where each of the first suppressing devices 60a and 60b are provided with a suppressor or a varistor, the first suppressing devices 60a and 60b are used as devices in which the absolute values of the positive voltage Vp and the negative voltage Vn exceed the predetermined value.

Assume that the first suppressing devices 60a and 60b each include the suppressor 70 or the varistor 71, and the second suppressing devices 64a and 64b each include the suppressor 70, the varistor 71, the Zener diode 73, or the diode clamping circuit 74. In this configuration, the absolute values of the positive voltage Vp and the negative voltage Vn of the second suppressing device 64a are preferably smaller than the absolute values of the positive voltage Vp and the negative voltage Vn of the first suppressing device 60a. Similarly, it is preferable that the absolute values of the positive voltage Vp and the negative voltage Vn of the second suppressing device 64b are smaller than the absolute values of the positive voltage Vp and the negative voltage Vn of the first suppressing device 60b.

When the ECU 3 is provided with the signal processing circuit 21, the conversion unit 22, and the microcomputer 24, and the first suppressing devices 60a and 60b of the ECU 3 each include a suppressor 70 or a varistor 71, the first suppressing devices 60a and 60b of the ECU 3 are used as devices in which the absolute values of the positive voltage Vp and the negative voltage Vn exceed a predetermined value. Furthermore, assume that, in the ECU 3, the first suppressing devices 60a and 60b each include the suppressor 70 or the varistor 71, and the second suppressing devices 64a and 64b each include the suppressor 70, the varistor 71, the Zener diode 73, or the diode clamping circuit 74. In this configuration, the absolute values of the positive voltage Vp and the negative voltage Vn of the second suppressing device 64a are preferably smaller than the absolute values of the positive voltage Vp and the negative voltage Vn of the first suppressing device 60a. Similarly, the absolute values of the positive voltage Vp and the negative voltage Vn of the second suppressing device 64b are preferably smaller than the absolute values of the positive voltage Vp and the negative voltage Vn of the first suppressing device 60b.

The absolute values of the positive voltage Vp and the negative voltage Vn of the suppressor 70 and the varistor 71 are comparatively large. The absolute values of the positive voltage Vp and the negative voltage Vn of the Zener diode 73 and the diode clamping circuit 74 are comparatively small. Thus, the Zener diode 73 and the diode clamping circuit 74 are each used as constituent elements of the second suppressing device 64a or the second suppressing device 64b.

### Effects of Signal Processing Circuit 21

The peak value of a signal that propagates through the signal line 5a is suppressed twice by the first suppressing device 60a and the second suppressing device 64a. The peak value of the signal that propagates through the signal line 5b is also suppressed twice by the first suppressing device 60b and the second suppressing device 64b. Thus, the peak values of two signals whose DC components have been removed by the corresponding capacitors Ca and Cb are reliably suppressed to small values. Also, as described above, when the absolute values of the positive voltage Vp and the negative voltage Vn of the second suppressing device 64a are respectively less than the absolute values of the positive voltage Vp and the negative voltage Vn of the first suppressing device 60a, and the absolute values of the positive voltage Vp and the negative voltage Vn of the second suppressing device 64b are respectively less than the absolute values of the positive voltage Vp and the negative voltage Vn of the first suppressing device 60b, the peak values are reliably suppressed to small values.

The greater the bitrate of the differential signals transmitted by the gateway 2 and the ECU 3, the more electrostatic noise affects the differential signals. Thus, the higher the bitrate of the differential signals, the greater the effect of the signal processing circuit 21. For example, when the bitrate of a differential signal is 1 Gbps or more, it is effective to use the signal processing circuit 21.

On the propagation paths of the two signals that propagate through the signal lines 5a and 5b, the terminal circuit 61 is disposed between the first suppressing circuit 60 and the second suppressing circuit 64. Thus, not only the application of a high voltage to the DC removing circuit 62 and the common mode choke coil 63, but also the application of a high voltage to the terminal circuit 61 is prevented.

### Variations

The common mode choke coil 63 may be a circuit for removing common mode noise. Thus, in place of the common mode choke coil 63, another circuit for removing common mode noise may be used. The terminal circuit 61 is not limited to a circuit including the capacitor C1, and may be a circuit in which a connection node between resistors Ra and Rb is grounded, for example.

The embodiments disclosed herein are to be considered illustrative in all respects and not restrictive. The scope of the present invention is defined by the claims and not by the above description, and all changes that come within the meaning and range of equivalency of the claims are intended to be embraced therein.

1. A receiving apparatus that receives a differential signal represented by a voltage difference between two signals that propagate through two signal lines, the receiving apparatus comprising:
a first suppressing circuit and a second suppressing circuit configured to suppress peak values of the two signals;
a DC removing circuit configured to remove DC components of the two signals; and
a noise removing circuit configured to remove common-mode noise included in the two signals,
wherein, on a propagation path of the two signals, the DC removing circuit and the noise removing circuit are disposed between the first and second suppressing circuits,
the differential signal propagates to the first suppressing circuit and the second suppressing circuit in this order,
the first suppressing circuit includes two first connection devices respectively connected at one end to the two signal lines,
if the voltage of the signal lines is a first threshold voltage, a current flows through the respective first connection devices,
the second suppressing circuit includes two second connection devices respectively connected at one end to the two signal lines,
if the voltage of the signal lines is a second threshold voltage, a current flows through the respective second connection devices,
the second threshold voltage is less than the first threshold voltage, and the two second connection devices each include a diode clamping circuit.

2. The receiving apparatus according to claim 1, further comprising:
a terminal circuit configured to suppress reflection of the two signals, wherein the terminal circuit is disposed on the propagation path, between the first suppressing circuit and the noise removing circuit.

3. The receiving apparatus according to claim 1, wherein the two first connection devices each include a suppressor or a varistor.

4. (canceled)

5. The receiving apparatus according to claim 2, wherein the two first connection devices each include a suppressor or a varistor.
